(19) United States
(12) Patent Application Publication
(10) Pub. No.: US 2025/0259860 A1
(43) Pub. Date: Aug. 14, 2025

(54) METHOD OF MANUFACTURING SEMICONDUCTOR PACKAGE

(71) Applicant: SAMSUNG ELECTRONICS CO., LTD., Suwon-si (KR)

(72) Inventors: Subin Jo, Suwon-si (KR); Myoungchul Eum, Suwon-si (KR); Jihwan Kim, Suwon-si (KR); Hansol Yoo, Suwon-si (KR)

(73) Assignee: SAMSUNG ELECTRONICS CO., LTD., Suwon-si (KR)

(21) Appl. No.: 18/807,251

(22) Filed: Aug. 16, 2024

(30) Foreign Application Priority Data
Feb. 8, 2024 (KR) 10-2024-0019793

(51) Int. Cl. H01L 21/56; C09J 7/30; C09J 183/04; H01L 23/00; H01L 23/31; H01L 23/552

(52) U.S. Cl. CPC H01L 21/566; C09J 7/30; C09J 183/04; H01L 23/3128; H01L 23/552; H01L 24/13; H01L 24/32; H01L 24/48; H01L 24/73; H01L 24/83; H01L 2224/13111; H01L 2224/32225; H01L 2224/73204; H01L 2224/73265; H01L 2224/82855; H01L 2924/3025

(57) ABSTRACT

A method of manufacturing a semiconductor package includes preparing a molding structure on which connection bumps are provided, forming a release layer at least partially filling spaces between the connection bumps, where the release layer includes a silicon (Si)-based polymer, forming an adhesive layer covering the release layer and the connection bumps, separating unit packages on which the release layer and the adhesive layer are formed by cutting the molding structure, the release layer, and the adhesive layer, attaching the unit packages to a base film by the adhesive layer, where the adhesive layer faces the base film, forming a shielding material layer covering at least a portion of each of the unit packages, at least a portion of the release layer, and at least a portion the adhesive layer, and separating the unit packages covered with the shielding material layer from the release layer.

### CROSS-REFERENCE TO RELATED APPLICATION(S)

This application is based on and claims priority to Korean Patent Application No. 10-2024-0019793, filed on Feb. 8, 2024, in the Korean Intellectual Property Office, the disclosure of which is incorporated by reference herein in its entirety.

### BACKGROUND

Example embodiments of the disclosure relate to a method of manufacturing a semiconductor package.

In order to protect users of electronic devices or semiconductor chips from electromagnetic interference (EMI), EMI shielding of semiconductor packages is required. Accordingly, manufacturing technology for semiconductor packages including an electromagnetic wave shielding layer is being developed.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a method of manufacturing a semiconductor package having improved reliability.

Additional aspects will be set forth in part in the description which follows and, in part, will be apparent from the description, or may be learned by practice of the presented embodiments.

According to an aspect of one or more embodiments, a method of manufacturing a semiconductor package may include preparing a molding structure on which connection bumps are provided, forming a release layer at least partially filling spaces between the connection bumps, where the release layer includes a silicon (Si)-based polymer, forming an adhesive layer covering the release layer and the connection bumps, separating unit packages on which the release layer and the adhesive layer are formed by cutting the molding structure, the release layer, and the adhesive layer, attaching the unit packages to a base film by the adhesive layer, where the adhesive layer faces the base film, forming a shielding material layer covering at least a portion of each of the unit packages, at least a portion of the release layer, and at least a portion the adhesive layer, separating the unit packages covered with the shielding material layer from the release layer, and removing residue of the release layer that is on the unit packages using an etchant including at least one of fluorine ions, hydroxide ions, and hydrogen ions.

According to an aspect of one or more embodiments, a method of manufacturing a semiconductor package may include preparing a molding structure on which connection bumps are provided, forming a release layer at least partially filling spaces between the connection bumps, forming an adhesive layer covering the release layer and the connection bumps, separating unit packages on which the release layer and the adhesive layer are formed by cutting the molding structure, the release layer, and the adhesive layer, attaching the unit packages to a base film, forming a shielding material layer covering at least a portion of each of the unit packages, at least a portion of the release layer, and at least a portion of the adhesive layer, and separating the unit packages covered with the shielding material layer from the release layer, where the release layer may include a first portion at least partially filling spaces between connection bumps that are adjacent to each other and a second portion at least partially covering a surface of each of the connection bumps, and a first thickness of the first portion of the release layer is different from a second thickness of the second portion of the release layer.

According to an aspect of one or more embodiments, a method of manufacturing a semiconductor package may include preparing a molding structure on which connection bumps are provided, forming a release layer at least partially filling spaces between the connection bumps, forming an adhesive layer covering the release layer and the connection bumps, separating unit packages on which the release layer and the adhesive layer are formed by cutting the molding structure, the release layer, and the adhesive layer, attaching the unit packages to a base film, forming a shielding material layer covering at least a portion of each of the unit packages, at least a portion of the release layer, and at least a portion of the adhesive layer, and separating the unit packages covered with the shielding material layer from the release layer, where the release layer may include polydimethylsiloxane (PDMS) or cross-linked silicone polymer.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a flowchart illustrating a method of manufacturing a semiconductor package according to one or more embodiments;

FIG. 2 is a cross-sectional view illustrating operation S101 of FIG. 1 according to one or more embodiments;

FIGS. 3A and 3B are cross-sectional views illustrating operation S102 of FIG. 1 according to one or more embodiments;

FIG. 4 is a cross-sectional view illustrating operation S103 of FIG. 1 according to one or more embodiments;

FIG. 5 is a cross-sectional view illustrating operation S104 of FIG. 1 according to one or more embodiments;

FIG. 6 is a cross-sectional view illustrating operation S105 of FIG. 1 according to one or more embodiments;

FIG. 7 is a cross-sectional view illustrating operation S106 of FIG. 1 according to one or more embodiments;

FIG. 8 is a cross-sectional view illustrating operations S107 and S108 of FIG. 1 according to one or more embodiments; and

FIGS. 9A and 9B are cross-sectional views illustrating semiconductor packages according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Unless otherwise specified, terms, such as “upper portion,” “upper surface,” “lower portion,” “lower surface,” “side surface,” etc. are based on the drawings, and may vary used in the directions in which components are actually arranged.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, the terms “covering” and “filling” may refer to a partial covering/filling or a full covering/filling as will be understood by one or ordinary skill in the art from the disclosure herein.

In addition, ordinal numbers, such as “first,” “second,” “third,” etc. may be used as labels for specific elements, steps, directions, etc. to distinguish various elements, steps, directions, etc. from each other. Terms that are not described using “first,” “second,” etc. in the specification may still be referred to as “first” or “second” in the claims. In addition, terms referenced by a particular ordinal number may be described elsewhere with a different ordinal number.

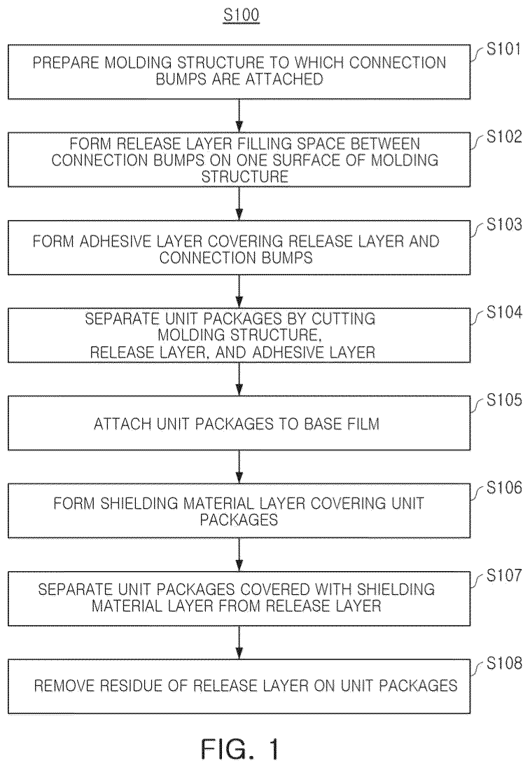

FIG. 1 is a flowchart illustrating a method S100 of manufacturing a semiconductor package according to one or more embodiments.

Referring to FIG. 1, the method S100 of manufacturing a semiconductor package according to one or more embodiments may include operation S101 of preparing a molding structure to which connection bumps are attached, operation S102 of forming a release layer filling a space between the connection bumps on one surface of the molding structure, operation S103 of forming an adhesive layer covering the release layer and the connection bumps on the molding structure, operation S104 of separating unit packages on which the release layer and the adhesive layer are formed by cutting the molding structure, the release layer, and the adhesive layer, operation S105 of attaching the unit packages to a base film, operation S106 of forming a shielding material layer covering at least a portion of each of the unit packages, the release layer, and the adhesive layer, and operation S107 of separating the unit packages covered with the shielding material layer from the release layer. According to one or more embodiments, the method S100 of manufacturing a semiconductor package may further include operation S108 of removing residues of the release layer on the unit packages.

According to one or more embodiments, by using a release layer including a silicon (Si)-based polymer, the unit packages may be mechanically separated from the release layer without an additional process to remove adhesive force between the release layer and the connection bumps. That is, the unit packages may be separated from the release layer while the release layer and the adhesive layer remain adhered to the base film. In addition, the release layer including a silicon (Si)-based polymer may sufficiently fill the space between adjacent connection bumps even if the size of the connection bumps, for example, a horizontal width and/or height, increases, thereby preventing the occurrence of voids and back-spill defects.

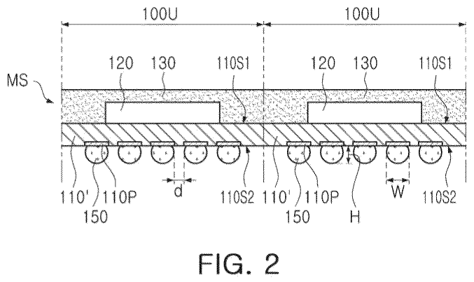

Hereinafter, the method S100 of manufacturing a semiconductor package according to one or more embodiments is described in detail with reference to FIGS. 2 to 8.

FIG. 2 is a cross-sectional view illustrating the operation S101 of FIG. 1 according to one or more embodiments.

Referring to FIGS. 1 and 2, a molding structure MS including a plurality of unit packages 100U may be prepared. The molding structure MS may include a substrate strip 110′, semiconductor chips 120, a mold layer 130, and connection bumps 150.

The substrate strip 110′ may include a plurality of package substrates (e.g., printed circuit boards (PCBs)) connected as one body. The semiconductor chips 120 may be electrically connected to a first surface 110S1 of the substrate strip 110′ using a flip-chip method or a wire bonding method. The semiconductor chips 120 may be provided in larger numbers than that shown in the drawing. For example, each of the plurality of unit packages 100U may include a plurality of semiconductor chips arranged vertically and/or horizontally on the substrate strip 110′ or the package substrate.

The semiconductor chips 120 may include logic chips, such as a central processing unit (CPU), a graphics processing unit (GPU), a field programmable gate array (FPGA), an application processor (AP), a digital signal processor, a cryptographic processor, a microprocessor, a microcontroller, an analog-to-digital converter, and application-specific integrated circuits (ASICs), and/or memory chips including volatile memories, such as dynamic random-access memory (RAM) (DRAM) static RAM (SRAM), etc., and nonvolatile memories, such as phase change RAM (PRAM), magnetic RAM (MRAM), resistive RAM (RRAM), flash memory, etc.

The mold layer 130 may include an insulating resin sealing the semiconductor chips 120, such as a thermosetting resin, such as an epoxy resin, a thermoplastic resin, such as polyimide, or prepreg, Ajinomoto build-up film (ABF), FR-4, bismaleimide-triazine (BT), epoxy molding compound (EMC), etc.

The connection bumps 150 may be arranged on a second surface 110S2 of the substrate strip 110′. The connection bumps 150 may be attached to a lower terminal 110P of the substrate strip 110′. The connection bumps 150 may include a low melting point metal, such as tin (Sn) or an alloy including tin (Sn) (e.g., Sn—Ag—Cu, Sn—Ag, etc.). According to one or more embodiments, the connection bumps 150 may have a form of a combination of a pillar and a ball.

A height H of the connection bumps 150 may be about 180 μm or greater. For example, the height H of the connection bumps 150 may be about 180 μm to about 400 μm, but is not limited thereto. A horizontal width W of the connection bumps 150 may be about 180 μm or greater. For example, the horizontal width W of the connection bumps 150 may be about 180 μm to about 400 μm, but is not limited thereto. A spacing d between adjacent connection bumps 150 may be about 180 μm to about 400 μm, but is not limited thereto. Since the connection bumps 150 are completely impregnated with a release layer to be described below, in the method S100 of manufacturing a semiconductor package of one or more embodiments, an electromagnetic wave shielding layer for a semiconductor package may be formed without restrictions depending on the size of the connection bumps 150.

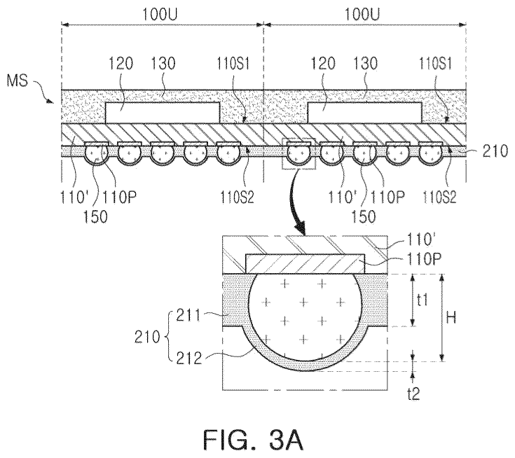

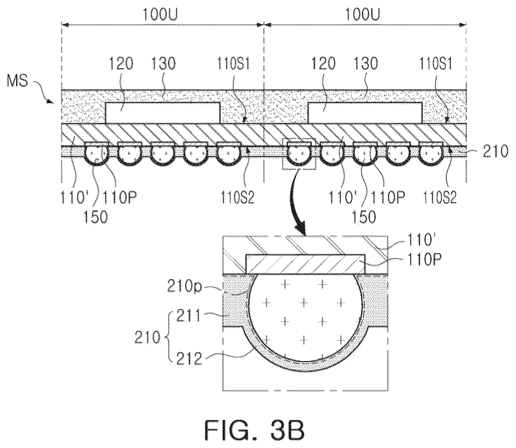

FIGS. 3A and 3B are cross-sectional views illustrating operation S102 of FIG. 1 according to one or more embodiments.

Referring to FIGS. 1 and 3A, a release layer 210 may be formed on the molding structure MS. The release layer 210 may be coated directly on the second surface 110S2 of the substrate strip 110′. The release layer 210 may be formed using, for example, spin coating or slit coating. The release layer 210 may include a silicon (Si)-based polymer.

The release layer 210 may include, for example, polydimethylsiloxane (PDMS) or cross-linked silicone polymer. In one or more embodiments, the release layer 210 may include a compound represented by Chemical Formula (1) or Chemical Formula (2) below. Chemical Formula (1) below represents a structural formula of PDMS, and Chemical Formula (2) below represents a polymerization formula of a cross-linked silicone polymer using methicone and vinyl dimethicone.

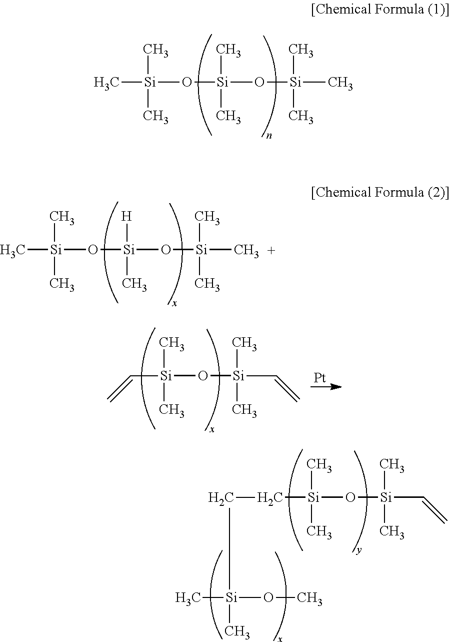

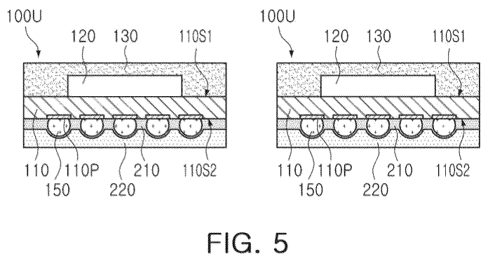

The viscosity of the release layer 210 may range from about 0.5 mPa's to about 30000 mPas, or from about 10 mPa's to about 1000 mPa's (@25° C.). If the viscosity of the release layer 210 exceeds about 30000 mPa s, filling properties of the release layer 210 between the connection bumps 150 may be reduced. If the viscosity of the release layer 210 is less than about 0.5 mPas, it may be difficult for the release layer 210 to cover curved surfaces of the connection bumps 150. In addition, in order to minimize the occurrence of debris during a sawing process of the release layer 210 (see FIG. 5), the elastic modulus of the release layer 210 may range from about 0.1 MPa to about 5 MPa or about 0.5 MPa to about 3 MPa, but is not limited thereto.

The release layer 210 may be formed using a silicon (Si)-based polymer mixed with various additives to have the aforementioned physical properties. For example, the release layer 210 of the example embodiment may be formed using a silicon (Si)-based polymer in which a polymer including silicon (Si) (e.g., PDMS, methicone, vinyl dimethicone, etc.) is mixed with a crosslinking agent at a ratio of about 5:1 to about 20:1.

The release layer 210 may include a first portion 211 filling the space between adjacent connection bumps 150 and a second portion 212 covering at least a portion of the curved surface of each of the connection bumps 150. The first portion 211 of the release layer 210 may cover ½ or more of the height H of the connection bumps 150. That is, the first portion 211 may extend from the surface 110S2 to at least half of the height H of the connection bumps 150. The second portion 212 of the release layer 210 may extend conformally along at least a portion of the curved surface of each of the connection bumps 150. A first thickness t1 of the first portion 211 of the release layer 210 and a second thickness t2 of the second portion 212 of the release layer 210 may be different from each other. The first thickness t1 of the first portion 211 of the release layer 210 may be ½ or more of the height H of the connection bumps 150. The second thickness t2 of the second portion 212 may be less than the first thickness t1 of the first portion 211 of the release layer 210. For example, the first thickness t1 of the first portion 211 of the release layer 210 may be about 90 μm to about 300 μm, but is not limited thereto. The first thickness t1 of the first portion 211 of the release layer 210 may be determined by considering the height H, horizontal width W, and spacing d of the connection bumps 150.

Referring to FIGS. 1 and 3B, according to one or more embodiments, an operation of surface-treating the molding structure MS and the connection bumps 150 may be further included before forming the release layer 210. A surface treatment layer 210p may be further formed between the release layer 210 and the molding structure MS and between the release layer 210 and the connection bumps 150. The surface treatment layer 210p may modify the surface of the connection bumps 150 and the molding structure MS to be hydrophobic, allowing the release layer 210 to be easily separated in a subsequent process. When the molding structure MS is separated from the release layer 210, the surface treatment layer 210p may suppress the occurrence of residues on the release layer 210 and prevent damage to the connection bumps 150. According to a process, a boundary between the surface treatment layer 210p and the release layer 210 may not be apparent. For example, when the release layer 210 includes PDMS, the surface treatment layer 210p may include a compound represented by Chemical Formula (3) below. The Chemical Formula (3) below represents hexamethyldisiloxane (HMDS).

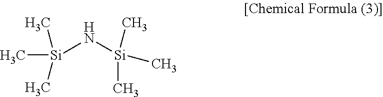

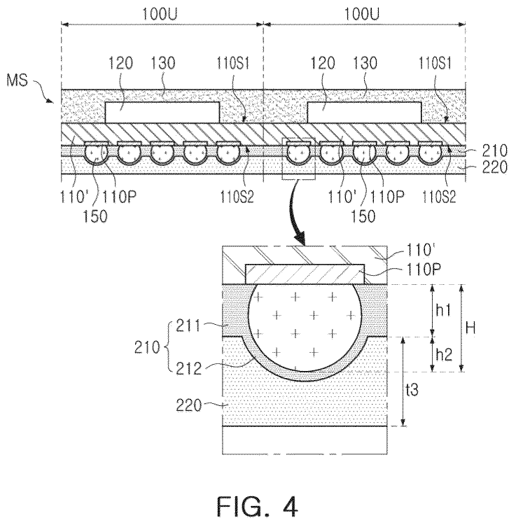

FIG. 4 is a cross-sectional view illustrating the operation S103 of FIG. 1 according to one or more embodiments.

Referring to FIGS. 1 and 4, an adhesive layer 220 may be formed on the molding structure MS. The adhesive layer 220 may be formed to cover the entire release layer 210 and the connection bumps 150 (e.g., the exposed surfaces of the connection bumps 150). The adhesive layer 220 may include a thermosetting polymer or a photocurable polymer. In one or more embodiments, the adhesive layer 220 may include thermosetting siloxane polymer or photocurable silicone acryl polymer.

The connection bumps 150 may include an upper region covered by the first portion 211 of the release layer 210 and a lower region covered by the second portion 212 of the release layer 210. A height h1 of the upper region of the connection bumps 150 may be equal to or greater than a height h2 of the lower region. A third thickness t3 of the adhesive layer 220 may be greater than the height h2 of the lower region of the connection bumps 150. For example, the third thickness t3 of the adhesive layer 220 may be about 100 μm to about 250 μm, but is not limited thereto. The third thickness t3 of the adhesive layer 220 may be determined by considering the height h2 of the lower region of the connection bumps 150, etc.

FIG. 5 is a cross-sectional view illustrating the operation S104 of FIG. 1 according to one or more embodiments.

Referring to FIGS. 1 and 5, unit packages 100U in which the release layer 210 and the adhesive layer 220 are formed may be separated. The unit packages 100U may include the package substrate 110 separated from the substrate strip 110′, at least one semiconductor chip 120, a mold layer 130 disposed on the upper surface 110S1 of the package substrate 110, and the connection bumps 150 disposed on the lower surface 110S2 of the package substrate 110. The unit packages 100U may be formed by cutting the molding structure MS, the release layer 210, and the adhesive layer 220. The molding structure MS, release layer 210, and adhesive layer 220 may be cut by a sawing process.

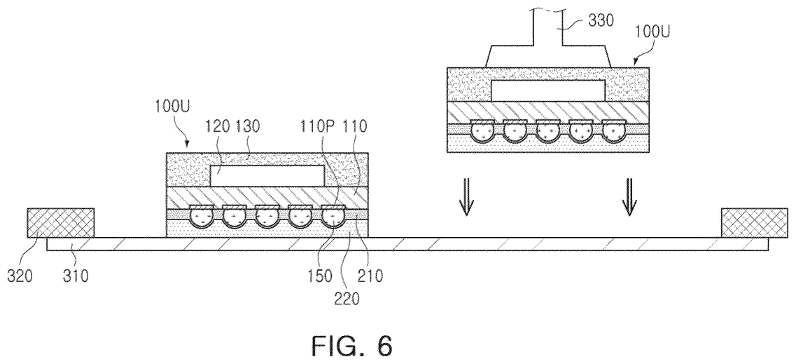

FIG. 6 is a cross-sectional view illustrating the operation S105 of FIG. 1 according to one or more embodiments.

Referring to FIGS. 1 and 6, the unit packages 100U may be attached to a base film 310. The unit packages 100U may be arranged so that the adhesive layer 220 faces the base film 310. The unit packages 100U may be arranged on the base film 310 pickup device 330 to be spaced apart from each other in a horizontal direction. A frame 320 may be attached to an end of the base film 310. The frame 320 may be formed of metal, but is not limited thereto. The base film 310 may be a film coated with an adhesive on at least one side thereof. For example, the base film 310 may include a polyimide (PI) film, a polyethylene terephthalate (PET) film, or a polyethylene-naphthalate (PEN) film.

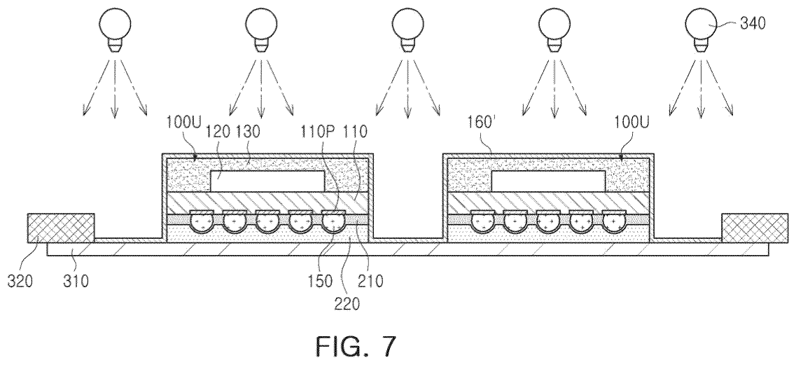

FIG. 7 is a cross-sectional view illustrating the operation S106 of FIG. 1 according to one or more embodiments.

Referring to FIGS. 1 and 7, a shielding material layer 160′ covering the unit packages 100U may be formed. The shielding material layer 160′ may cover at least a portion of each of the unit packages 100U, the release layer 210, and the adhesive layer 220. The shielding material layer 160′ may be conformally formed by a coating device 340. The coating device 340 may form the shielding material layer 160′ by performing a deposition process, such as physical vapor deposition (PVD) or chemical vapor deposition (CVD). For example, the coating device 340 may be a sputtering device, but is not limited thereto.

The shielding material layer 160′ may be a thin film formed on the surface of each of the unit packages 100U, the release layer 210, and the adhesive layer 220. A thickness of the shielding material layer 160′ may be about 5 μm or less, but is not limited thereto. The shielding material layer 160′ may include a conductive material for electromagnetic interference (EMI) shielding, such as iron (Fe), nickel (Ni), gold (Au), silver (Ag), copper (Cu), and alloys thereof. The shielding material layer 160′ may include at least one conductive thin film. For example, the shielding material layer 160′ may be a three-layer thin film in which a stainless steel (SUS) film, a copper (Cu) film, and a stainless steel (SUS) film are sequentially stacked.

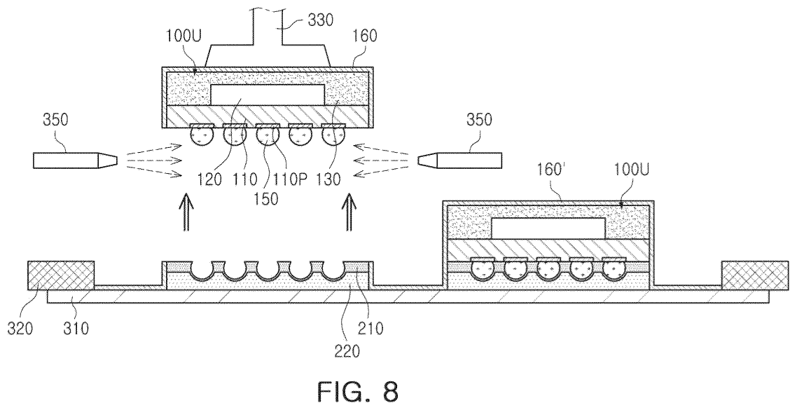

FIG. 8 is a cross-sectional view illustrating the operations S107 and S108 of FIG. 1 according to one or more embodiments.

Referring to FIGS. 1 and 8, the unit packages 100U on which an electromagnetic wave shielding layer 160 is formed (i.e., by the shielding material layer 160′) may be separated from the release layer 210. The pickup device 330 may pick up the unit packages 100U on which the shielding material layer 160′ is formed. Since the release layer 210 has a relatively weak adhesive force compared to the adhesive layer 220, the unit packages 100U may be separated from the release layer 210 by the pickup device 330, and the shielding material layer 160′ may be cut to form the electromagnetic wave shielding layer 160 covering the unit packages 100U. In this manner, according to the method S100 of manufacturing a semiconductor package of one or more embodiments, the unit packages 100U may be separated without an additional process to remove the adhesive force between the release layer 210 and the connection bumps 150. That is, the unit packages 100U may be separated while the release layer 210 and the adhesive layer 220 remain adhered to the base film 310.

According to one or more embodiments, an operation of removing residues of the release layer 210 on the unit packages 100U may be further performed. The residues of the release layer 210 may be removed by a wet etching process using an etchant. For example, the etchant may be sprayed toward the lower surfaces and/or connection bumps 150 of the unit packages 100U using a nozzle 350. The etchant may include at least one of fluorine ions (F−), hydroxide ions (OH−), and hydrogen ions (H+). For example, the etchant may remove the residues of the release layer 210 through a reaction of Chemical Formula (4) below. Chemical Formula (4) below represents a decomposition reaction of silicon-based polymer by an etchant including tetra-n-butylammonium fluoride (TBMF).

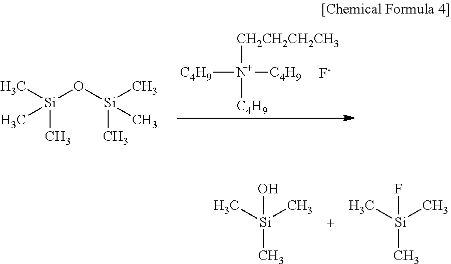

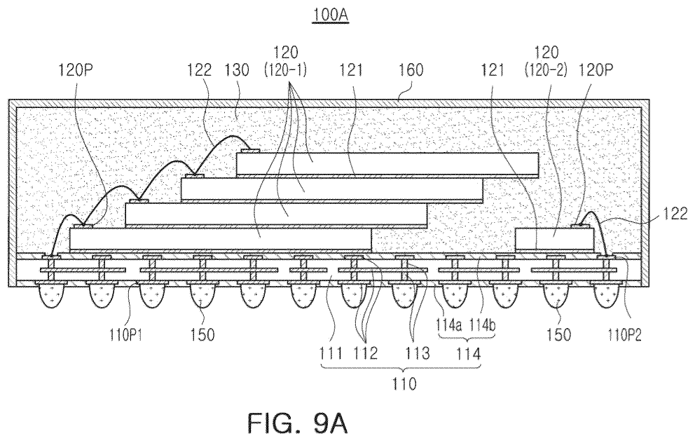

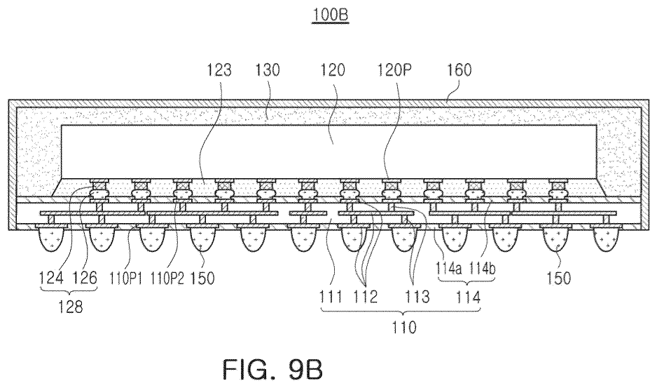

FIGS. 9A and 9B are cross-sectional views of semiconductor packages according to one or more embodiments. FIGS. 9A and 9B illustrate semiconductor packages formed by the manufacturing method of FIG. 1, respectively.

Referring to FIG. 9A, the semiconductor package 100A of one or more embodiments may include a package substrate 110, a plurality of semiconductor chips 120, a mold layer 130, connection bumps 150, and an electromagnetic wave shielding layer 160.

The package substrate 110 may be a semiconductor package substrate including a PCB, a ceramic substrate, a glass substrate, or a tape wiring substrate. For example, the package substrate 110 may be a double-sided PCB or a multi-layer PCB. The package substrate 110 may include an insulating layer 111, interconnection patterns 112, and interconnection vias 113.

The insulating layer 111 may include, for example, a thermosetting resin, such as an epoxy resin, a thermoplastic resin, such as polyimide, a prepreg including an inorganic filler or/and glass fiber (glass cloth or glass fabric), ABF, FR-4, and the like. The insulating layer 111 may include a plurality of insulating layers stacked in a vertical direction. For example, the insulating layer 111 may include a core layer and a build-up layer stacked on an upper surface and/or a lower surface of the core layer. According to a process, the boundaries between the plurality of insulating layers may not be apparent. According to one or more embodiments, the insulating layer 111 may include a photosensitive resin, such as photo imageable dielectric (PID).

The interconnection patterns 112 may form an electrical connection path within the insulating layer 111. The interconnection patterns 112 may include, for example, at least one of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C), or alloys including two or more metals thereof. Each of the interconnection patterns 112 may be formed of electrolytically deposited (ED) copper foil, rolled-annealed (RA) copper foil, ultra-thin copper foil, sputtered copper, copper alloys, and the like. The interconnection patterns 112 may include a plurality of pattern layers spaced apart from each other in the vertical direction. A plurality of pattern layers may extend in the horizontal direction on each vertical level. The interconnection patterns 112 may include fewer or more pattern layers than those shown in the drawing. The interconnection patterns 112 may include lower connection terminals 110P1 and upper connection terminals 110P2. The lower connection terminals 110P1 may be a pad portion of the lowermost interconnection patterns 112, and the upper connection terminals 110P2 may be a pad portion of the uppermost interconnection patterns 112.

The interconnection vias 113 may electrically connect the interconnection patterns 112 within the insulating layer 111. The interconnection vias 113 may include, for example, at least one of copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and carbon (C) or alloys including two or more metals thereof. The interconnection vias 113 may include a conductive material completely filling a via hole penetrating through at least a portion of the insulating layer 111 or include a conductive material conformally formed along the wall of the via hole. According to one or more embodiments, at least some of the interconnection vias 113 may be formed such that a conductive material is applied along the wall of the via hole and an internal space of the via hole surrounded by the conductive material is filled with an insulating material.

The package substrate 110 may further include a protective layer 114. The protective layer 114 may be formed on upper and/or lower surface of the insulating layer 111. For example, the protective layer 114 may include a lower protective layer 114a and an upper protective layer 114b. The lower protective layer 114a may include an opening exposing at least a portion of the lower connection terminals 110P1. The upper protective layer 114b may include an opening exposing at least a portion of the upper connection terminals 110P2. The protective layer 114 may be formed using, for example, solder resist.

A plurality of semiconductor chips 120 may be mounted on the package substrate 110. The plurality of semiconductor chips 120 may be electrically connected to the package substrate 110 using a wire bonding method. The plurality of semiconductor chips 120 may be attached to the package substrate 110 and other vertically adjacent semiconductor chips 120 using an adhesive film 121. The adhesive film 121 may include an inorganic adhesive or a polymer adhesive. The polymer adhesive may include, for example, a thermosetting polymer, a thermoplastic polymer, or a hybrid resin that is a mixture of the thermosetting polymer and the thermoplastic polymer. Connection pads 120P of the plurality of semiconductor chips 120 may be electrically connected to upper connection terminals 110P2 through a bonding wire 122. The plurality of semiconductor chips 120 may be bare semiconductor chips without separate bumps or interconnection layers, but are not limited thereto and the plurality of semiconductor chips 120 may be packaged-type semiconductor chips. The plurality of semiconductor chips 120 may include a semiconductor wafer including semiconductor elements, such as silicon, germanium or a semiconductor compound, such as silicon carbide (SiC), gallium arsenide (GaAs), indium arsenide (InAs), and indium phosphide (InP) and an integrated circuit (IC) formed on the semiconductor wafer. The plurality of semiconductor chips 120 may include different types of semiconductor chips 120-1 and 120-2. For example, the plurality of semiconductor chips 120 may include a plurality of first semiconductor chips 120-1 and at least one second semiconductor chip 120-2. According to one or more embodiments, at least some of the plurality of semiconductor chips 120 may be mounted using a flip-chip method.

The plurality of first semiconductor chips 120-1 may be memory semiconductor chips. The plurality of first semiconductor chips 120-1 may include nonvolatile memory devices, such as flash memory, PRAM, MRAM, ferroelectric random access memory (FeRAM), and RRAM and volatile memory devices, such as DRAM and SRAM. The flash memory may be, for example, V-NAND flash memory. The plurality of first semiconductor chips 120-1 may be shifted in at least one direction so that each of the connection pads 120P is exposed upwardly, but the stacked form of the plurality of first semiconductor chips 120-1 is not limited to that illustrated in the drawings. The plurality of first semiconductor chips 120-1 may be electrically connected to each other through the bonding wires 122.

The at least one second semiconductor chip 120-2 may be a control semiconductor chip. The at least one second semiconductor chip 120-2 may include various active and/or passive devices, such as field effect transistors (FETs) including planar FETs and FinFETs, logic devices, such as AND, OR, NOT, system large-scale integration (LSI) circuit, complementary metal-oxide semiconductor (CMOS) image sensor (CIS), and micro-electromechanical systems (MEMS).

The at least one second semiconductor chip 120-2 may control access to data stored in the plurality of first semiconductor chips 120-1. At least one second semiconductor chip 120-2 may control write/read operations of the plurality of first semiconductor chips 120-1 according to control commands from an external host. The at least one second semiconductor chip 120-2 may perform wear leveling, garbage collection, bad block management, and error correction code (ECC). The at least one second semiconductor chip 120-2 may be disposed to be spaced apart from the plurality of first semiconductor chips 120-1, but embodiments are not limited thereto.

The mold layer 130 may seal the plurality of semiconductor chips 120 on the package substrate 100. The mold layer 130 may cover each of the plurality of first semiconductor chips 120-1 and the at least one second semiconductor chip 120-2. The mold layer 130 may include, for example, an EMC.

The connection bumps 150 may be arranged on the lower surface of the package substrate 110. The semiconductor package 100A may be electrically connected to an external device, such as a module substrate or main board through the connection bumps 150. The connection bumps 150 may include, for example, tin (Sn) or an alloy including tin (Sn) (e.g., Sn—Ag—Cu, Sn—Ag, etc.). The connection bumps 150 may have the size described above with reference to FIG. 2, but are not limited thereto. In the method of manufacturing a semiconductor package of one or more embodiments, the electromagnetic wave shielding layer 160 may be formed without restrictions depending on the size of the connection bumps 150.

The electromagnetic wave shielding layer 160 may cover the package substrate 110 and the mold layer 130. The electromagnetic wave shielding layer 160 may be formed using a conformal shielding method. For example, the electromagnetic wave shielding layer 160 may extend to have a substantially constant thickness along the side surface of the package substrate 100 and the side surface and upper surface of the mold layer 130. According to one or more embodiments, the electromagnetic wave shielding layer 160 may be connected to a ground pattern among the interconnection patterns 112. The electromagnetic wave shielding layer 160 may be formed by, for example, a PVD method. According to one or more embodiments, the electromagnetic wave shielding layer 160 may be formed by a spray method. The electromagnetic wave shielding layer 160 may include a metal material, such as copper (Cu) or stainless steel, but is not limited thereto.

Referring to FIG. 9B, a semiconductor package 100B of one or more embodiments may include the package substrate 110, at least one semiconductor chip 120, the mold layer 130, the connection bumps 150, and the electromagnetic wave shielding layer 160. The semiconductor package 100B may include substantially the same or similar components as the semiconductor package 100A illustrated in FIG. 9A, except that at least one semiconductor chip 120 is mounted in a flip-chip manner. Accordingly, corresponding components are referred to by the same or similar reference numerals, and redundant descriptions may be omitted below.

The at least one semiconductor chip 120 may be disposed such that an active surface on which the connection pads 120P are arranged faces the package substrate 110. The at least one semiconductor chip 120 may be a bare semiconductor chip without a separate bump or interconnection layer, but is not limited thereto and the at least one semiconductor chip 120 may be a packaged-type semiconductor chip. The at least one semiconductor chip 120 may be electrically connected to the upper connection terminals 110P2 through conductive bumps 128. The conductive bumps 128 may include a pillar portion 124 and a solder portion 126. The pillar portion 124 may include copper (Cu) or an alloy of copper (Cu), and the solder portion 126 may include a low melting point metal, for example, tin (Sn) or an alloy (Sn—Ag—Cu) including tin (Sn). According to one or more embodiments, the conductive bumps 128 may include only the pillar portion 124 or only the solder portion 126. At least one semiconductor chip 120 may be a logic chip including a CPU, a GPU, an FPGA, an AP, a digital signal processor, a cryptographic processor, a microprocessor, a microcontroller, an analog-to-digital converter, an ASIC, and the like. According to one or more embodiments, the at least one semiconductor chip 120 may further include a memory chip including volatile memories, such as DRAM, SRAM and nonvolatile memories, such as PRAM, MRAM, RRAM, and flash memory.

According to one or more embodiments, the method of manufacturing a semiconductor package having improved reliability may be provided by introducing the release layer filling a space between the connection bumps.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

1. A method of manufacturing a semiconductor package, the method comprising:
preparing a molding structure on which connection bumps are provided;
forming a release layer at least partially filling spaces between the connection bumps, wherein the release layer comprises a silicon (Si)-based polymer;
forming an adhesive layer covering the release layer and the connection bumps;
separating unit packages on which the release layer and the adhesive layer are formed by cutting the molding structure, the release layer, and the adhesive layer;
attaching the unit packages to a base film by the adhesive layer, wherein the adhesive layer faces the base film;
forming a shielding material layer covering at least a portion of each of the unit packages, at least a portion of the release layer, and at least a portion the adhesive layer;
separating the unit packages covered with the shielding material layer from the release layer; and
removing residue of the release layer that is on the unit packages using an etchant comprising at least one of fluorine ions, hydroxide ions, and hydrogen ions.

2. The method of claim 1, wherein the unit packages are separated from the release layer while the release layer and the adhesive layer remain adhered to the base film.

3. The method of claim 1, wherein the release layer comprises polydimethylsiloxane (PDMS) or cross-linked silicone polymer.

4. The method of claim 3, wherein the release layer comprises polydimethylsiloxane (PDMS); and
wherein the method further comprises surface-treating the molding structure and the connection bumps before forming the release layer.

5. The method of claim 4, wherein a surface treatment layer between the release layer and the molding structure and between the release layer and the connection bumps comprises hexamethyldisiloxane (HMDS).

6. The method of claim 1, wherein the release layer is formed by a spin coating process.

7. The method of claim 1, wherein the release layer comprises a first portion at least partially filling spaces between connection bumps that are adjacent to each other and a second portion extending along a surface of at least a portion of each of the connection bumps.

8. (canceled)

9. The method of claim 7, wherein a first thickness of the first portion of the release layer is at least half of a height of the connection bumps.

10. The method of claim 9, wherein the height of the connection bumps ranges from about 180 μm to about 350 μm.

11. The method of claim 1, wherein the adhesive layer comprises a thermosetting polymer or a photocurable polymer.

12. The method of claim 11, wherein the adhesive layer comprises siloxane polymer or silicone acryl polymer.

13. (canceled)

14. The method of claim 1, wherein the etchant comprises tetra-n-butylammonium fluoride (TBMF).

15. The method of claim 1, wherein the molding structure comprises:
a substrate strip;
semiconductor chips provided on a first surface of the substrate strip; and
a mold layer sealing the semiconductor chips, and
wherein the connection bumps are provided on a second surface of the substrate strip.

16. The method of claim 1, wherein each of the unit packages comprises:
a package substrate separated from a substrate strip;
a semiconductor chip; and
a mold layer sealing the semiconductor chip and provided on an upper surface of the package substrate, and
wherein the connection bumps are provided on a lower surface of the package substrate.

17. (canceled)

18. (canceled)

19. A method of manufacturing a semiconductor package, the method comprising:
preparing a molding structure on which connection bumps are provided;
forming a release layer at least partially filling spaces between the connection bumps;
forming an adhesive layer covering the release layer and the connection bumps;
separating unit packages on which the release layer and the adhesive layer are formed by cutting the molding structure, the release layer, and the adhesive layer;
attaching the unit packages to a base film;
forming a shielding material layer covering at least a portion of each of the unit packages, at least a portion of the release layer, and at least a portion of the adhesive layer; and
separating the unit packages covered with the shielding material layer from the release layer,
wherein the release layer comprises a first portion at least partially filling spaces between connection bumps that are adjacent to each other and a second portion at least partially covering a surface of each of the connection bumps, and
wherein a first thickness of the first portion of the release layer is different from a second thickness of the second portion of the release layer.

20. (canceled)

21. The method of claim 20, wherein each of the connection bumps comprise an upper region at least partially covered by the first portion of the release layer and a lower region at least partially covered by the second portion of the release layer,
wherein a height of the upper region is equal to or greater than a height of the lower region, and
wherein a third thickness of the adhesive layer is greater than the height of the lower region of the connection bumps.

22. The method of claim 19, wherein the second portion of the release layer extends conformally along at least a portion of the surface of each of the connection bumps.

23. A method of manufacturing a semiconductor package, the method comprising:
preparing a molding structure on which connection bumps are provided;
forming a release layer at least partially filling spaces between the connection bumps;
forming an adhesive layer covering the release layer and the connection bumps;
separating unit packages on which the release layer and the adhesive layer are formed by cutting the molding structure, the release layer, and the adhesive layer;
attaching the unit packages to a base film;
forming a shielding material layer covering at least a portion of each of the unit packages, at least a portion of the release layer, and at least a portion of the adhesive layer; and
separating the unit packages covered with the shielding material layer from the release layer,
wherein the release layer comprises polydimethylsiloxane (PDMS) or cross-linked silicone polymer.

24. The method of claim 23, wherein the adhesive layer comprises silicone acryl polymer.

25. The method of claim 23, wherein the base film comprises polyimide (PI), polyethylene terephthalate (PET), or polyethylene-naphthalate (PEN).
